(19) United States
(12) Patent Application Publication
(10) Pub. No.: US 2024/0289510 A1
(43) Pub. Date: Aug. 29, 2024

(54) SYSTEMS AND METHODS FOR PRODUCT DISASSEMBLY SEQUENCE PLANNING

(71) Applicant: Accenture Global Solutions Limited, Dublin 4 (IE)

(72) Inventors: Kumar Abhinav, Hazaribag District (IN); Alpana Dubey, Bangalore (IN); Suma Mani Kuriakose, Mumbai (IN); Bharat Ladrecha, Bikaner (IN)

(21) Appl. No.: 18/115,676

(22) Filed: Feb. 28, 2023

(51) Int. Cl. G06F 30/17; G06F 30/27; G06N 3/0442; G06N 3/0455

(52) U.S. Cl. CPC G06F 30/17; G06F 30/27; G06N 3/0442; G06N 3/0455

(57) ABSTRACT

Systems and methods that support functionality for performing disassembly sequence planning are disclosed. The systems and methods may obtain 3D model data for a product to be disassembled and may convert the 3D model to one or more graph-based representations. An encoder is provided to generate a set of embeddings based on the one or more graph-based representations. A decoder is provided to generate disassembly data based on the set of embeddings. In an aspect, the disassembly data may indicate an order in which each component is to be removed during disassembly of the product and a direction in which each component should be removed.

### TECHNICAL FIELD

The present disclosure is generally related to manufacturing processes and more specifically, to techniques for performing disassembly sequence planning for disassembly of a product based on 3D model data.

### BACKGROUND

Effective disassembly sequence planning (DSP) helps increase the viability of a circular economy. Product disassembly has environmental and economic benefits, as it not only helps in better maintenance of products, but also helps to recover parts and materials when the product reaches its end-of-life (EOL). These recovered parts could be valuable components for other products. Effective disassembly also helps in the separation of precious and hazardous materials, thus reducing the overall environmental impact during EOL.

The task of disassembly sequence planning involves generating a feasible order in which the components of a product are to be removed without any interference between them. Over the years, the problem of disassembly sequence planning has been explored using different methods to generate a feasible sequence automatically. However, to generate a feasible disassembly sequence plan, traditional approaches use optimization-based methods, including mathematical programming (e.g., optimizing a cost function using linear programming), search methods with heuristic rules to prune the search space and speed up the search process, or use evolutionary algorithms like a genetic algorithm and its variants (e.g., ant colony optimization and the artificial bee colony algorithm). These algorithms are more robust in finding feasible disassembly sequences in lesser time as compared to global search methods. Despite extensive prior work, disassembly sequence planning remains a challenging task as it requires deductions on both discrete parameters (i.e., direction in which a component should be removed) and discrete actions (i.e., which component is to be removed in each step), leading to combinatorial explosion and significantly increasing the complexity of finding a feasible disassembly sequence plan.

### SUMMARY

Embodiments of the present disclosure provide systems and methods for performing disassembly sequence planning in a manner that can produce an order or sequence in which components of a product should be disassembled and a disassembly direction for each component that indicates a direction each component should be removed during disassembly. To perform disassembly sequence planning, a 3D model, such as a computer aided design (CAD) model may be obtained. The CAD model may represent the product for which disassembly sequence planning is to be performed. After obtaining the CAD model, an assembly descriptor may be utilized to generate graph-based representations of the product and its components. For example, the graph-based representations may include an assembly graph indicating the components (e.g., as nodes) and relationships between the nodes (e.g., edges indicating relationships between the components). Additionally, the graph-based representations may include component graphs for each component of the product. The component graphs may include nodes representing surfaces or faces of the components, where edges between nodes of the component graph(s) indicate relationships between the surfaces of faces of the component.

An encoder/decoder configured to generate disassembly data based on the graph-based representations may be provided. The encoder may be configured to convert the graph-based representations into a set of embeddings for the components (or the product). The decoder may be configured to determine disassembly sequence data based on the set of embeddings. In an aspect, the decoder may additionally be configured to determine a disassembly direction for each component. The disassembly data may indicate an order in which each component is to be removed during disassembly of the product, while the disassembly direction data may indicate a direction of removal for each component.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF DRAWINGS

For a more complete understanding of the disclosed methods and apparatuses, reference should be made to the implementations illustrated in greater detail in the accompanying drawings, wherein:

FIG. 1 is a block diagram for performing disassembly sequence planning in accordance with aspects of the present disclosure;

FIG. 2A is a block diagram aspects of performing disassembly sequence planning in accordance with aspects of the present disclosure;

FIGS. 2B and 2C are block diagrams illustrating relationships between components that may be considered during disassembly sequence planning in accordance with aspects of the present disclosure;

FIG. 3A is a block diagram of an exemplary assembly graph for disassembly sequence planning in accordance with aspects of the present disclosure;

FIG. 3B is an image of a CAD model of a component suitable for disassembly sequence planning in accordance with aspects of the present disclosure;

FIG. 3C is a block diagram of a component graph of the CAD model of FIG. 3B generated during disassembly sequence planning operations performed in accordance with aspects of the present disclosure;

FIG. 4A is a diagram illustrating exemplary aspects of performing disassembly sequence planning for a rod piston in accordance with aspects of the present disclosure;

FIGS. 4B and 4C illustrate exemplary considerations for using CAD models to perform disassembly sequence planning in accordance with aspects of the present disclosure;

FIG. 4D is a diagram illustrating aspects of using attention for disassembly sequence planning in accordance with aspects of the present disclosure;

FIGS. 5A-5D are block diagrams illustrating exemplary aspects of an architecture for performing disassembly sequence planning in accordance with aspects of the present disclosure;

FIGS. 6A-6E show block diagrams illustrating exemplary operations for performing message passing during generation of graph embeddings in accordance with aspects of the present disclosure;

FIG. 7 is a block diagram illustrating exemplary operations determining a disassembly removal direction for a component in accordance with aspects of the present disclosure;

FIG. 8 is a diagram illustrating a coordinate system having pre-determined directions for disassembly sequence planning in accordance with aspects of the present disclosure; and

FIG. 9 is a flow diagram of an exemplary method for performing disassembly sequence planning in accordance with aspects of the present disclosure.

It should be understood that the drawings are not necessarily to scale and that the disclosed embodiments are sometimes illustrated diagrammatically and in partial views. In certain instances, details which are not necessary for an understanding of the disclosed methods and apparatuses or which render other details difficult to perceive may have been omitted. It should be understood, of course, that this disclosure is not limited to the particular embodiments illustrated herein.

### DETAILED DESCRIPTION

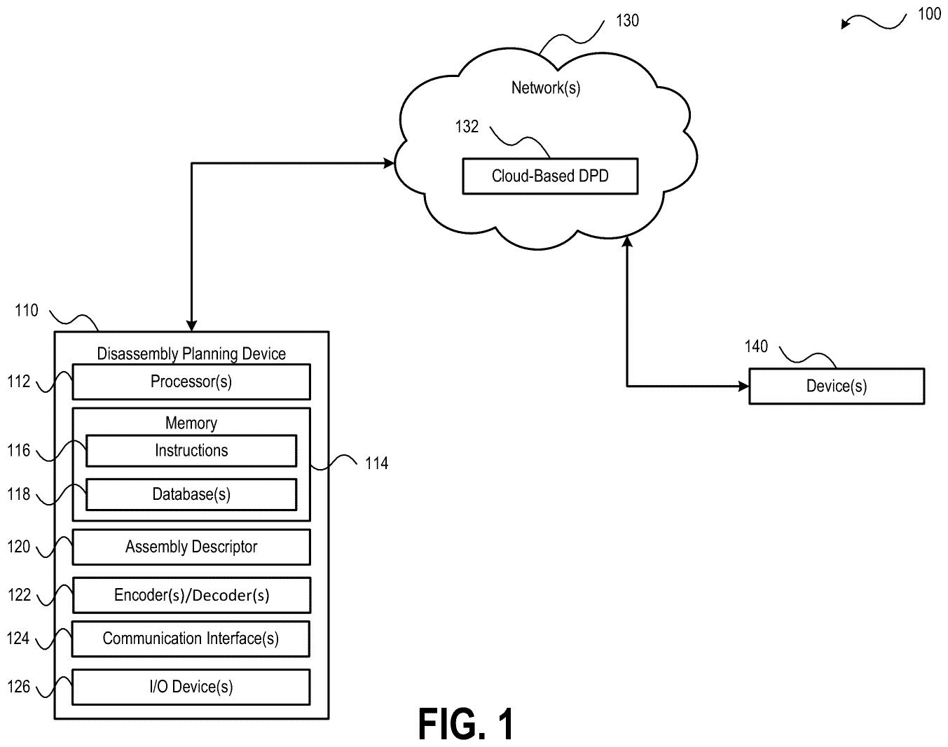

Referring to FIG. 1, a block diagram for performing disassembly sequence planning in accordance with aspects of the present disclosure is shown. As shown in FIG. 1, the system 100 includes a disassembly planning device 110 having one or more processors 112, a memory 114, an assembly descriptor 120, an encoder/decoder 122, one or more communication interfaces 124, and one or more input/output (I/O) device 126. The one or more processors 112 may include one or more microcontrollers, application specific integrated circuits (ASICs), field programmable gate arrays (FPGAs), central processing units (CPUs) having one or more processing cores, or other circuitry and logic configured to facilitate the operations of the firewall analysis device 110 in accordance with aspects of the present disclosure. The memory 114 may include random access memory (RAM) devices, read only memory (ROM) devices, erasable programmable ROM (EPROM), electrically erasable programmable ROM (EEPROM), one or more hard disk drives (HDDs), one or more solid state drives (SSDs), flash memory devices, network accessible storage (NAS) devices, or other memory devices configured to store data in a persistent or non-persistent state. Software configured to facilitate operations and functionality of the disassembly planning device 110 may be stored in the memory 114 as instructions 116 that, when executed by the one or more processors 112, cause the one or more processors 112 to perform the operations described herein with respect to the disassembly planning device 110, as described in more detail below. Additionally, the memory 114 may be configured to store in one or more databases 118. The one or more databases 118 may include databases storing 3D models, disassembly sequence plans generated by the disassembly planning device 110, or other types of data described herein (e.g., graphs, embeddings, etc.).

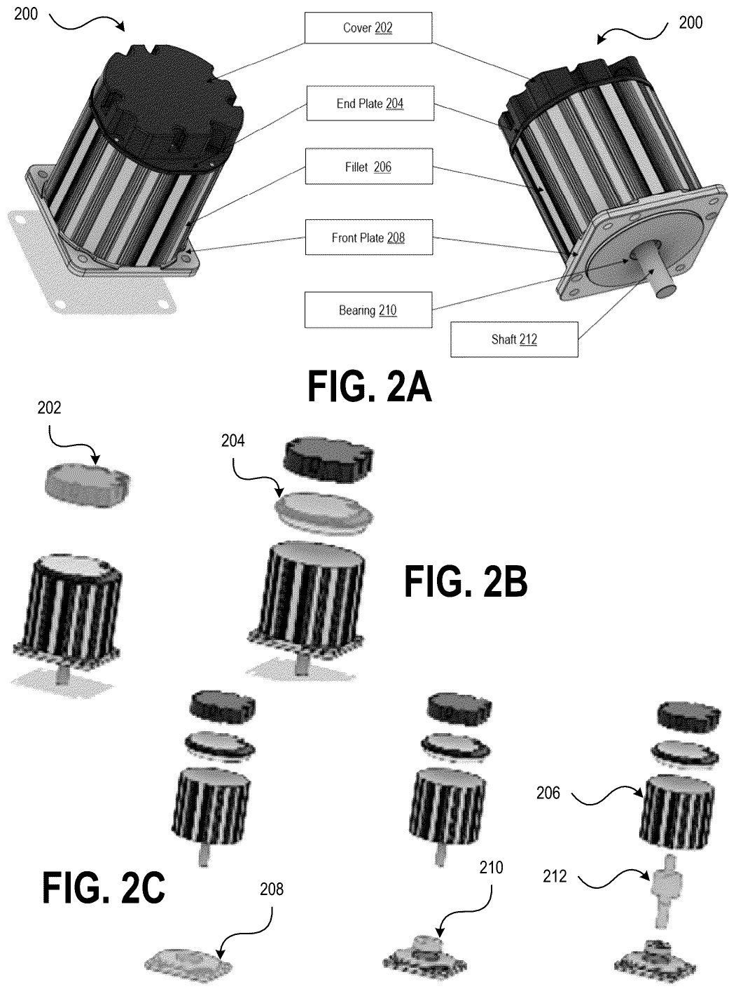

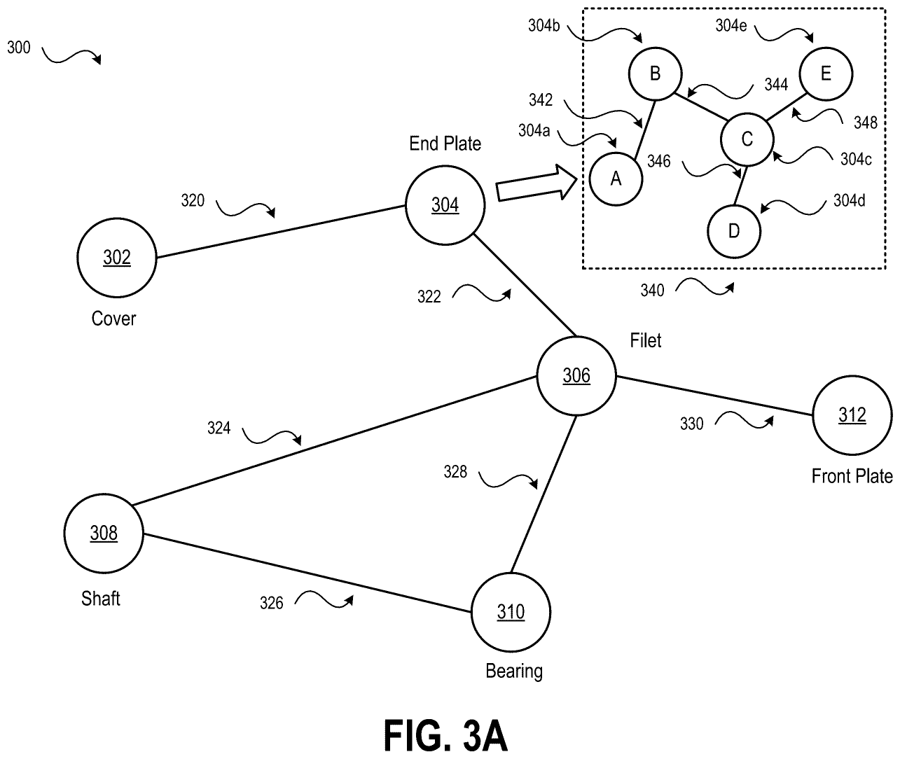

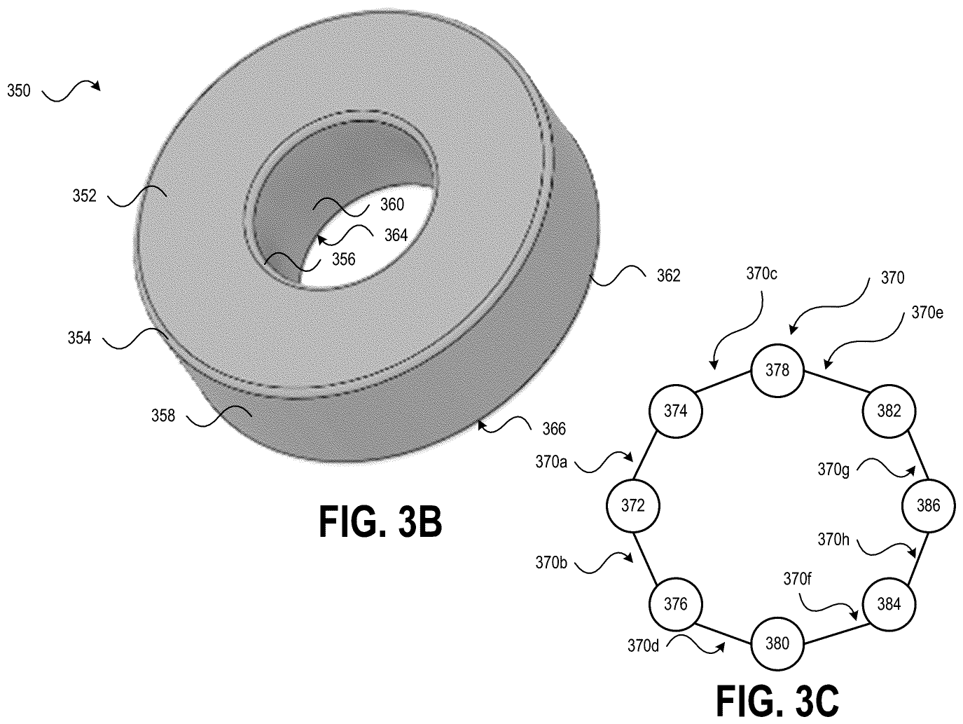

The assembly descriptor 120 may be configured to analyze a 3D model of a product and generate one or more graph-based representations of the product, as depicted in the 3D model. For example, the product may include a plurality of different components. The graph-based representations may provide information associated with an arrangement of or relationships between the components, as well as information associated with the structure of the components themselves (e.g., shape, size, etc.). Exemplary techniques for generating graph-based representations suitable for use with performing disassembly sequence planning techniques in accordance with the present disclosure are described in more detail below with reference to FIGS. 2A-3C.

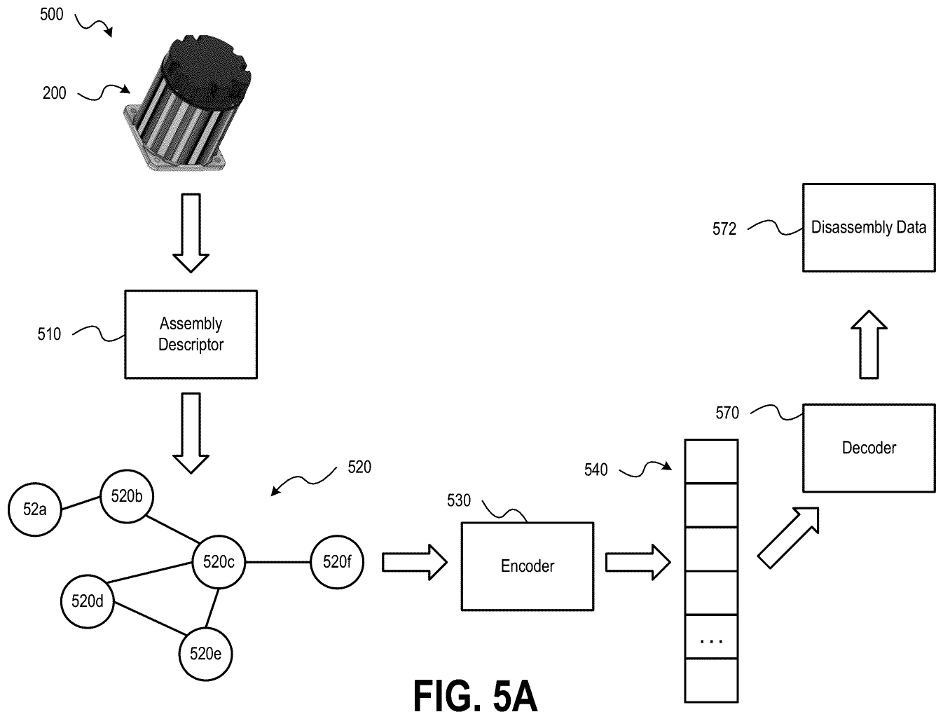

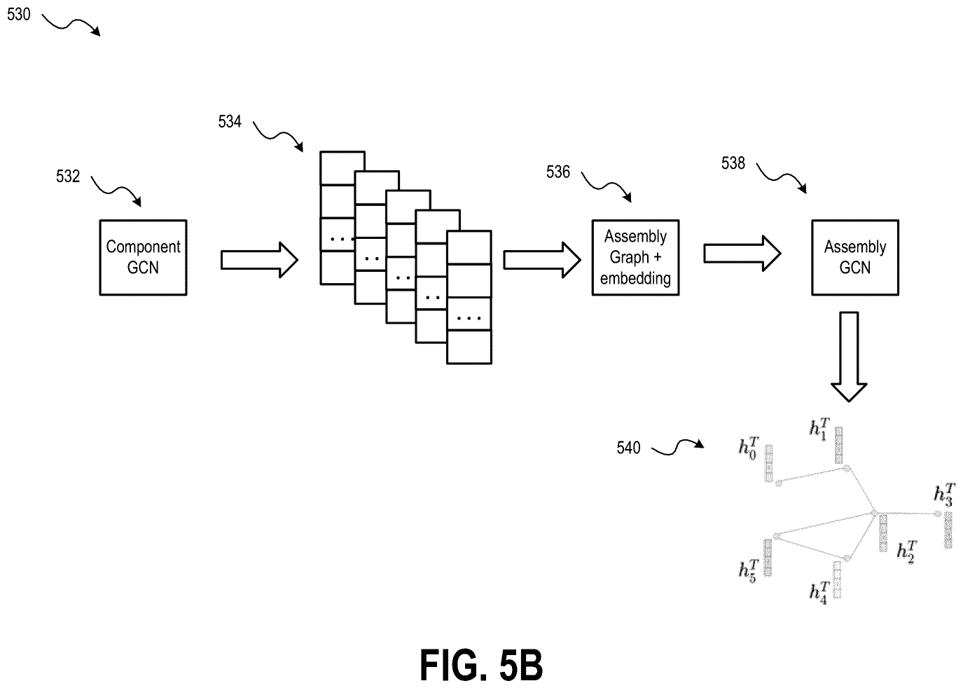

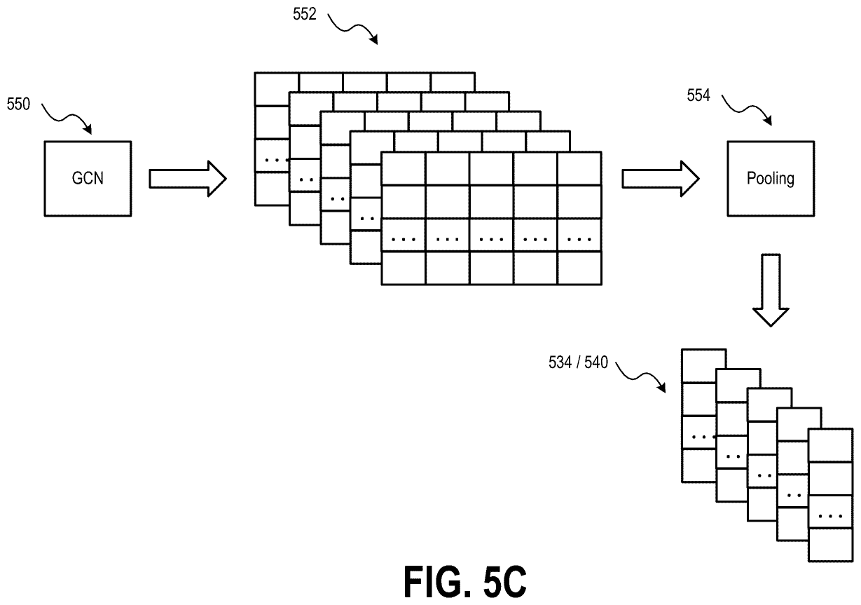

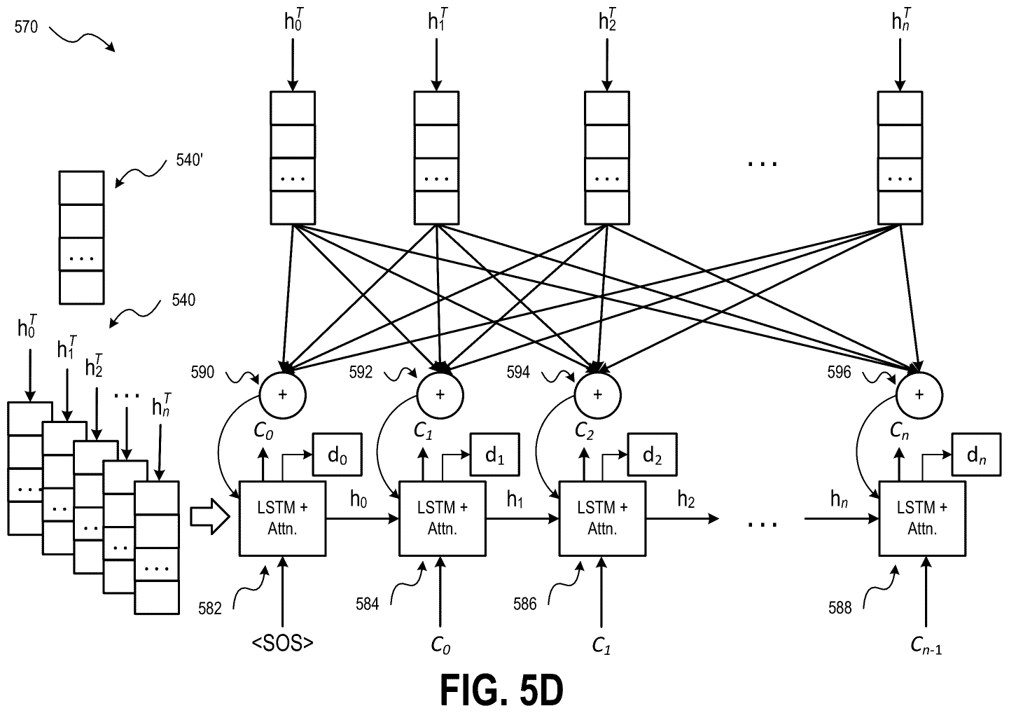

The encoder/decoder 122 may be configured to generate disassembly sequence data that identifies an order for performing disassembly of a product based on the graph-based representation(s) generated by the assembly descriptor. In an aspect, the encoder/decoder 122 may include an encoder configured to accept the graph-based representations from the assembly descriptor as inputs and output a set of graph embeddings. The set of graph embeddings may be provided to a decoder of the encoder/decoder 122, which may be configured to generate the disassembly data. The disassembly data may include the order in which each component of the set of components of the product represented by the model should be removed during disassembly and may additionally indicate a direction in which each component should be removed. Exemplary details regarding operations of the encoder/decoder 122 are described in more detail below with reference to FIGS. 5A and 5D-8.

The one or more communication interfaces 124 may be configured to communicatively couple the disassembly planning device 110 to one or more networks 130 via wired or wireless communication links established according to one or more communication protocols or standards (e.g., an Ethernet protocol, a transmission control protocol/internet protocol (TCP/IP), an Institute of Electrical and Electronics Engineers (IEEE) 802.11 protocol, and an IEEE 802.16 protocol, a 3rd Generation (3G) communication standard, a 4th Generation (4G)/long term evolution (LTE) communication standard, a 5th Generation (5G) communication standard, and the like). The one or more input/output I/O devices 124 may include one or more display devices, a keyboard, a stylus, one or more touchscreens, a mouse, a trackpad, a camera, one or more speakers, haptic feedback devices, or other types of devices that enable a user to receive information from or provide information to the disassembly planning device 110.

The disassembly planning device 110 may be communicatively coupled to one or more computing device 140 via the one or more networks 130. For example, the disassembly planning device 110 may be a server or other type of shared computing device providing functionality for performing disassembly sequence planning in accordance with the techniques disclosed herein. A user of the computing device 140 may access the functionality provided by the disassembly planning device 110 via the network(s) 130 to perform disassembly sequence planning for one or more products. In an aspect, the computing device(s) 140 may also include robots configured to perform disassembly operations. In some implementations, the functionality of the disassembly planning device 110 may be provided via a cloud-based implementation, shown in FIG. 1 as cloud-based disassembly planning device 132. Exemplary details regarding operations for disassembly sequence planning in accordance with the present disclosure are described in more detail below with reference to FIGS. 2A-9.

Referring to FIG. 2A, a block diagram aspects of performing disassembly sequence planning in accordance with aspects of the present disclosure are shown. In the example of FIG. 2A, a diagram illustrating components of an electric motor 200 are shown. As shown in FIG. 2A, the electric motor 200 includes a cover 202, an end plate 204, a fillet 206, a front plate 208, a bearing 210, and a shaft 212. Relationships between each of these components are shown in FIGS. 2B and 2C. For example, FIG. 2B illustrates that the cover 202 is an outermost component of the motor 200 and that the end plate 204 sits between the cover 202 and the fillet 206. It can be seen in FIG. 2C that the front plate 208 is a bottommost component of the motor 200 and that the bearing 210 and the shaft 212 are internal components of the motor 200. It is noted that the exemplary components of the motor 200 shown and described with reference to FIGS. 2A-2C have been provided for purposes of illustration, rather than by way of limitation and that the motor 200 may include additional components that are not shown in FIGS. 2A-2C for simplicity of the disclosure. As an example, the motor 200 may additionally include screws or other types of connectors to hold the various components shown in FIGS. 2A-2C together in an assembled state. Furthermore, it should be understood that the motor 200 shown in FIGS. 2A-2C may be part of a larger assembly, and that operations described herein for performing disassembly sequence planning with respect to the motor 200 may be performed as part of a larger disassembly sequence plan in which the motor 200 is removed from the larger assembly and then disassembled.

As explained above with reference to FIG. 1, an assembly descriptor (e.g., the assembly descriptor 120 pf FIG. 1) may be used to perform disassembly sequence planning of the motor 200 in accordance with the concepts disclosed herein. The assembly descriptor may be configured to capture information associated with component boundary representation (B-Rep) surface and adjacency relationships, as well as component topology information. In an aspect, the information associated component B-Rep surface and adjacency relationships and the component topology information may be extracted from a Standard for the Exchange of Product Data (STEP) file associated with a product (assembly). It is noted that STEP files used by disassembly sequence planning processes in accordance with the present disclosure may comply with one or more STEP file standards (e.g., ISO 10303, STP file formats, P21-File formats, STEP Physical File formats, and the like). The STEP file may include information associated with the complete body of one or more components included in a 3D model, rather than just the geometry of each component, thereby providing a high level of detail with regard to the components of the 3D model.

The assembly descriptor may use the captured information to generate a graph-based representation of a 3D model. For example, an assembly descriptor may generate a graph-based representation of the components of the motor 200. In an aspect, the graph-based representation may include an assembly graph representing connections between the different components. For example, as explained above with reference to FIGS. 2A-2C, the motor 200 represents an assembly made up of several components (e.g., the cover 202, the end plate 204, the fillet 206, the front plate 208, the bearing 210, and the shaft 212). The assembly associated with the motor 200 may be represented using a graph which includes the contact information between different components in it. The nodes Nₐ of the graph represent the components, and the edges Eₐ between the nodes represent the contact relationship between the corresponding components.

To illustrate and referring to FIG. 3A, a block diagram of an exemplary assembly graph for disassembly sequence planning in accordance with aspects of the present disclosure is shown as an assembly graph 300. As shown in FIG. 3A, the assembly graph 300 for the motor 200 includes a set of nodes Nₐ that includes nodes 302, 304, 306, 308, 310, 312, where the node 302 corresponds to the cover 202, the node 304 corresponds to the end plate 204, the node 306 corresponds to the fillet 206, the node 308 corresponds to the shaft 212, the node 310 corresponds to the bearing 210, and the node 312 corresponds to the front plate 208 of FIG. 2A.

As shown in FIG. 3A, the nodes 302, 304, 306, 308, 310, 312 of the assembly graph 300 are connected by a set of edges Eₐ that includes edges 320-330, with the edge 320 connecting the nodes 302, 304 (e.g., to represent the relationship between the cover 202 and the end plate 204 (e.g., the cover 202 is adjacent or contacting the end plate 204), the edge 322 connecting the nodes 304, 306 (e.g., to represent the relationship between the end plate 204 and the fillet 206 (e.g., the end plate 204 is adjacent or contacting the fillet 206), the edge 324 connecting the nodes 306, 308 (e.g., to represent the relationship between the fillet 206 and the end plate shaft 212 (e.g., the fillet 206 is adjacent or contacting the shaft 212), the edge 326 connecting the nodes 308, 310 (e.g., to represent the relationship between the shaft 212 and the bearing 210 (e.g., the shaft 212 is adjacent or contacting the bearing 210), the edge 328 connecting the nodes 306, 310 (e.g., to represent the relationship between the fillet 206 and the bearing 210 (e.g., the fillet 206 is adjacent or contacting the bearing 210), and the edge 330 connecting the nodes 306, 312 (e.g., to represent the relationship between the fillet 206 and the front plate 208 (e.g., the fillet 206 is adjacent or contacting the front plate 208). As can be appreciated from the foregoing, the relationships indicated by the arrangement of the nodes and edges of the assembly graph provide information related to the arrangement of the various components of the motor 200 in an as-assembled state (i.e., the state from which a disassembly sequence will be performed).

In an aspect, the graph-based representation generated by the assembly descriptor may additionally include a component graph for each component. The component graph may capture additional information associated with the assembly for which disassembly sequence planning is being performed. For example, a product assembly is made of multiple components (e.g., the motor 200 includes the components 202-212 shown in FIGS. 2A-2C) and each component represents a body that cannot be further separated into sub parts. These components in 3D space are represented by connected faces, which may be represented by a component graph generated by the assembly descriptor. The component graph may include a set of nodes N_{c}, which represent the faces on the corresponding component, and a set of edges E_{c}, which represent the connectivity between adjacent faces.

For example and referring to FIG. 3A, a component graph generated in accordance with aspects of the present disclosure is shown as a component graph 340. The component graph 340 may correspond to a component graph of the component associated with node 304 (i.e., the end plate 204 of FIGS. 2A-2C) and has a set of nodes N_{c} and a set of edge Nₑ. The set of nodes N_{c} includes nodes 304a, 304b, 304c, 304d, 304e and the set of edges Nₑ includes edges 342, 344, 346, 348. As will be described in more detail below with reference to FIGS. 3B and 3C, the nodes 304a, 304b, 304c, 304d, 304e may represent faces of the component associated with node 304 (i.e., the end plate 204 of FIGS. 2A-2C) and the set of edges 342, 344, 346, 348 may represent relationships or connections between the faces of the component. In an aspect, each component graph has a set of node level features nfc, which represent geometric features (e.g., geometric features determined based on the B-Rep faces derived from the STEP file). In an aspect, the node level features nfc may be represented as: 100 3D points sampled from each B-Rep face, 100 normals at these points, and 100 trimming mask binary values denoting whether the sample points are contained inside/outside the B-Rep face trimming boundary. It is noted that the example above lists a specific number of sampled points, normal, and trimming mask values for purposes of illustration rather than by way of limitation and that other values may be used in accordance with the concepts disclosed herein. Furthermore, it is noted that sampled points, normal, and trimming mask may be used to simplify datasets used by the techniques disclosed herein. For example, a component of a 3D model may include thousands or millions of points, each having a normal. The trimming mask may specify a distribution of these points such that the sampled points include points sufficiently distributed across all surfaces of the component(s) so that an accurate representation of the component's surfaces is represented by the sampled point. Such sampling reduces the amount of data maintained in the (component) graphs while ensuring the graphs contain accurate information regarding the components and their surfaces.

In implementations where the assembly descriptor generates a graph-based representation that includes both the assembly graph and the component graph, the graph-based representation may be generated as a bi-level graph that includes both the assembly graph and the component graph. The assembly descriptor may represent the assembly and component graphs using adjacency matrix. In an aspect, the assembly graph does not contain any discrete node (i.e., component) feature vectors, which are represented by the information maintained in the component graph. In such an implementation, every node in the assembly graph has the corresponding component graph as its feature, while the component graph includes a set of node level features nfc, as described above. In other words, the assembly graph represents components themselves (e.g., via the nodes of the assembly graph) and relationships between different components (e.g., via the edges of the assembly graph), while nodes of the component graph(s) represent individual features of a component (e.g., face information) and the edges of the component graph represent relationships between individual component features (e.g., relationships between the faces of a component), as explained in more detail below with reference to FIGS. 3B and 3C.

Referring to FIG. 3B, an image of a CAD model of a component suitable for disassembly sequence planning in accordance with aspects of the present disclosure as a CAD model 350 is shown. In an aspect, the CAD model 350 may represent the bearing 210 of FIGS. 2A-2C described above. As shown in FIG. 3B, the CAD model 350 includes a set of faces 352, 354, 356, 358, 360, 362, 364, 366, which correspond to the surfaces of the component represented by the CAD model 350. As explained above, a component graph may be generated that represents the information shown in the CAD model 350, such as by extracting information from a STEP file.

Referring to FIG. 3C, a block diagram of a component graph of the CAD model of FIG. 3B generated during disassembly sequence planning operations performed in accordance with aspects of the present disclosure is shown as a component graph 370. As shown in FIG. 3C, the component graph 370 includes a set of nodes Nc that includes nodes 372, 374, 376, 378, 380, 382, 384, 386, and a set of edges Ec that includes edges 370a, 370b, 370c, 370d, 370e, 370f, 370g, 370h. The node 372 may represent the face 352 of FIG. 3B, the node 374 may represent the face 354 of FIG. 3B, the node 376 may represent the face 356 of FIG. 3B, the node 378 may represent the face 358 of FIG. 3B, the node 380 may represent the face 360 of FIG. 3B, the node 382 may represent the face 362 of FIG. 3B, the node 384 may represent the face 364 of FIG. 3B, and the node 386 may represent the face 366 of FIG. 3B. As explained above, the component graph 370 may capture information associated with a set of node level features nfc, which represent geometric features (e.g., geometric features determined based on the B-Rep faces derived from the STEP file) associated with each node. For example, the nodes 372-386 may each capture a set of node level features nf_{c} for the corresponding face of the CAD model 350 of FIG. 3B. In an aspect, the node level features nf_{c} for each node may be represented as: 100 3D points sampled from each B-Rep face, 100 normals at these points, and 100 trimming mask binary values denoting whether the sample points are contained inside/outside the B-Rep face trimming boundary. It is noted that the exemplary node level features described above have been provided for purposes of illustration, rather than by way of limitation and that other representations of node level features may be utilized if desired.

As explained above, the set of edges Ec of the component graph 370 may represent relationships between the different faces of the component shown in the CAD model of FIG. 3B. For example, the edge 37 a indicates the face 352 (represented by node 372) is adjacent or connected to the face 354 (represented by node 374); the edge 370b indicates the face 352 (represented by node 372) is adjacent or connected to the face 356 (represented by node 376); the edge 370c indicates the face 354 (represented by node 374) is adjacent or connected to the face 358 (represented by node 378); the edge 370d indicates the face 356 (represented by node 376) is adjacent or connected to the face 360 (represented by node 380); the edge 370e indicates the face 358 (represented by node 378) is adjacent or connected to the face 362 (represented by node 382); the edge 370f indicates the face 360 (represented by node 380) is adjacent or connected to the face 364 (represented by node 384); the edge 370g indicates the face 362 (represented by node 382) is adjacent or connected to the face 366 (represented by node 386); and the edge 370h indicates the face 364 (represented by node 384) is adjacent or connected to the face 366 (represented by node 386).

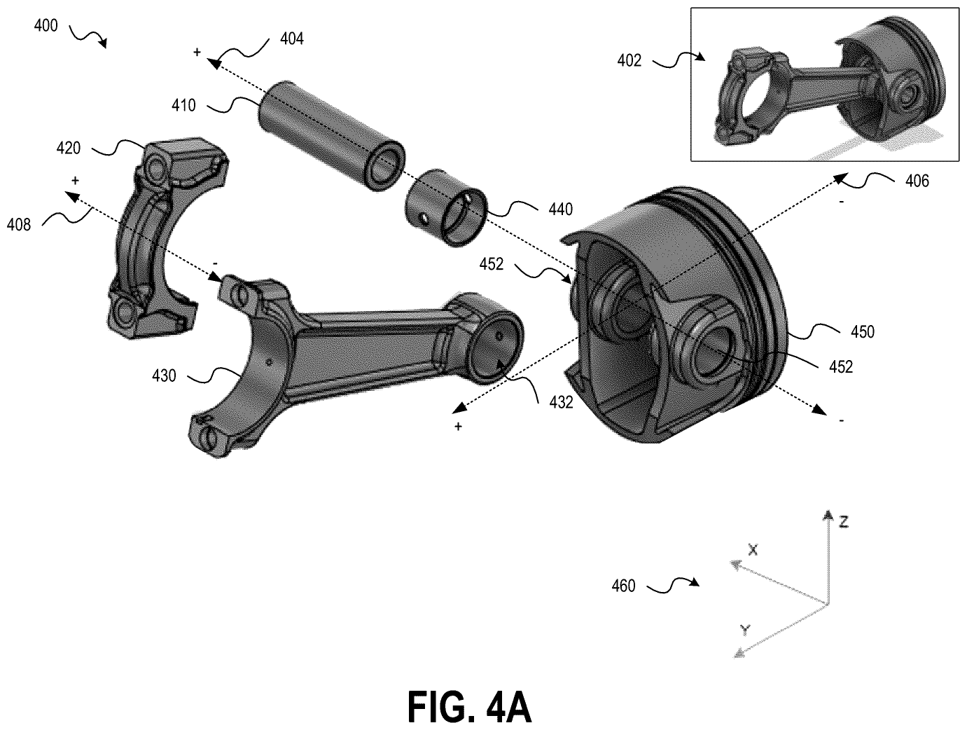

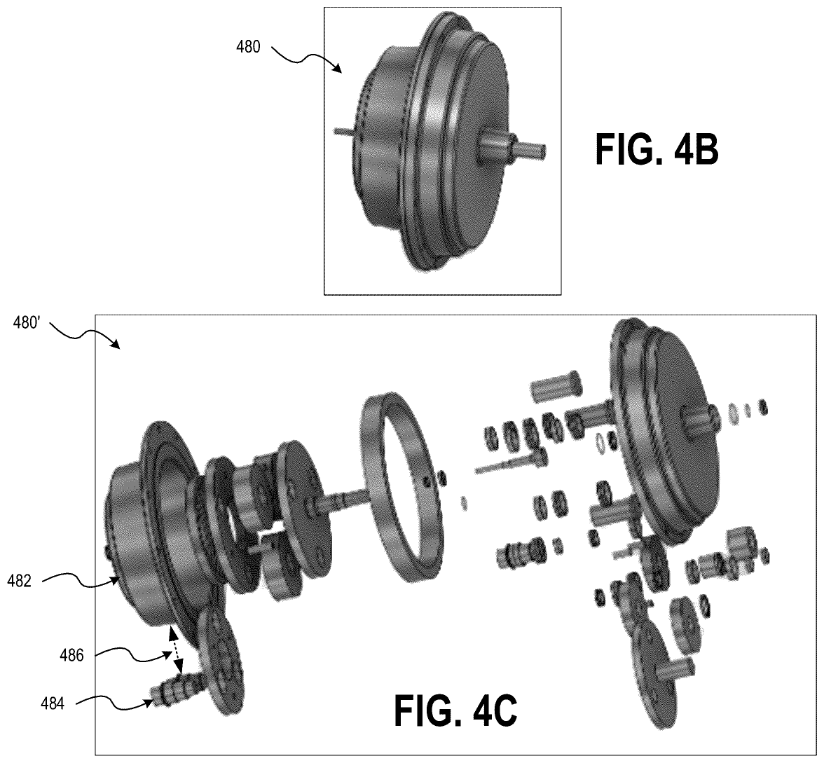

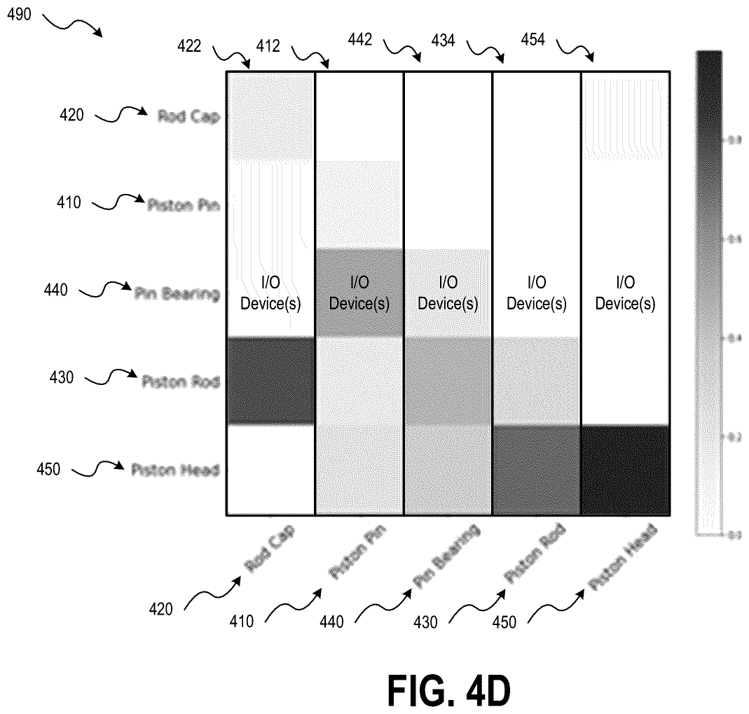

As can be appreciated from the description of FIGS. 2A-3C above, assembly descriptors in accordance with aspects of the present disclosure enable generation of graph-based representations of 3D components and assemblies. As will be described in more detail below, the information captured by graph-based representations generated by assembly descriptors in accordance with aspects of the present disclosure may provide information that may be used to perform disassembly sequence planning in accordance with the concepts disclosed herein. It is also to be appreciated that while the exemplary techniques for generating graph-based representations of 3D components and assemblies for use in performing disassembly sequence planning may leveraging information extracted form CAD files generated using existing CAD tools, the use of such information does not cause disassembly sequences determined in accordance with the concepts disclosed herein to be limited in the same manner as existing CAD tools, as will be described in more detail below, such as with reference to FIGS. 4A-4C.

Referring to FIG. 4A, a diagram illustrating exemplary aspects of performing disassembly sequence planning for a rod piston in accordance with aspects of the present disclosure is shown. In the example shown in FIG. 4A, a rod piston assembly 402 is shown and includes a piston pin 410, a rod cap 420, a piston rod 430, a piston bearing 440, and a piston head 450. It is noted that the exemplary components of the rod piston assembly 402 shown in FIG. 4A are provided for purposes of illustration, rather than by way of limitation and that the rod piston assembly 402 may include additional components not explicitly shown in FIG. 4A, such as screws, nuts, or other components to aid in connecting the various components together and securing them in place. Furthermore, it should be understood that the rod piston assembly 402 may be a component of a larger assembly and that disassembly sequence planning techniques in accordance with aspects of the present disclosure may be readily applied to such larger assemblies or assemblies and parts having different types of components than those shown in FIG. 4A.

As can be seen in FIG. 4A, the components of the rod piston assembly 402 may not be disassembled by removing each component in a same direction. In particular, the piston pin 410 and the piston bearing 440 may be removed from the piston head 450 in the direction of longitudinal axis 404, which may be substantially similar to the x axis of legend 460. Similarly, the rod cap 420 may be removed from the piston rod 430 in the direction of longitudinal axis 404, which may be substantially similar to the x axis of legend 460. In an aspect, the direction of removal may be indicated in different directions along a single axis. For example, in FIG. 4, the piston pin 410 and the piston bearing 440 are removed from the piston head 450 in a positive (+) direction of the longitudinal axis 404, and the rod cap 420 may be removed from the piston rod 430 in a positive (+) direction of the longitudinal axis 408. Furthermore, FIG. 4A illustrates that the piston rod 430 is to be removed from the piston head 450 along a longitudinal axis 406, which may correspond to a y axis in the legend 460. In some aspects, a disassembly sequence plan for removing the piston rod 430 may indicate the piston rod 430 is to be removed from the piston head 450 in a positive (+) direction of the longitudinal axis 406. It is further noted that while embodiments of the present disclosure may determine one or more axes and directions along those axes for which disassembly should be performed, the axes determine for disassembly operations are limited to the cardinal axes (e.g., an x, y, z axis) shown in the legend 460 and may include dynamically determined axes that are offset from one or more of the cardinal axes (e.g., an axis that is offset along both the x and y axes or is offset along the x, y, and z axes). Accordingly, it should be understood that disassembly sequences planned in accordance with the concepts disclosed herein may involve movement of components along more than 3 axes in some implementations. Additionally, while embodiments of the present disclosure are capable of determining multiple axes for use in disassembly sequence planning, a disassembly sequence plan determined using the concepts disclosed herein may involve movement of components along a single axis for some (simpler) component assemblies.

As briefly explained above, some CAD tools provide functionality for showing an exploded view of 3D designs for components and assemblies, but such exploded views fail to account for interactions and relationships between different components. As an illustrative example, screenshots showing an assembled view 480 and an exploded view 480′ of a 3D assembly designed using a CAD tool are shown in FIGS. 4B and 4C, respectively. As can be seen in FIG. 4C, the assembly 480 includes many different components. Using the exploded view capability of the CAD tool, each of the components may be moved such that each component is visible from a particular view, such as a perspective as shown in FIG. 4C. In generating the exploded view, the CAD tool merely moves the components so that each is visible without considering whether the movements used during the generation of the exploded view are actually possible. For example, in the assembled view 480′ it can be seen that the exploded view moved a component 484 in a direction 486 such that the component 484 passed through the side of component 482. Clearly, such movement would not be feasible in the real world because the component 482 is of a solid form factor and the component 484 could not simply be pulled through such a solid structure. Accordingly, it should be appreciated that while CAD tools can provide a user with visibility into the various components that are present in an assembly, the exploded view capability of such CAD tools does not enable disassembly sequence planning to be generated directly from the exploded view or a combination of the assembled and exploded views.

To further illustrate the concepts above, and as can be appreciated from the example shown in FIG. 4A, a process for performing disassembly of the rod piston assembly 402 may require components to be removed in a specific order and/or by removing components in a specific direction. For example, in the piston rod assembly 402 of FIG. 4A, the piston pin 410 and the piston bearing 440 may pass through an aperture 432 of the piston rod 430 and apertures 452 of the piston head 450. Therefore, the piston pin 410 and the piston bearing 440 may need to be removed from the piston head 450 (and from the aperture 432 of the piston rod 430) prior to removing the piston rod 430 from the piston head 450. Furthermore, as the piston head 450 is a solid component, the piston pin 410 and the piston bearing 440 cannot be removed from the piston head 450 in the direction of the z axis or the y axis of the legend 460 since portions of the piston head 450, which is a solid structure, would prevent movement of the piston pin 410 and the piston bearing 440 in those directions. Accordingly, a disassembly sequence plan for disassembling the piston rod assembly 402 must take into account relationships between components when determining directionality for removing different components and the order in which components should be removed during disassembly.

Referring to FIG. 5A, a block diagram providing an overview of architecture for determining a disassembly sequence in accordance with aspects of the present disclosure is shown as a disassembly sequence architecture 500. As can be seen in FIG. 5A, the disassembly sequence architecture 500 may receive, as input, one or more 3D models (e.g., CAD models), shown in FIG. 5A as a 3D model of the motor 200 of FIGS. 2A-2C. The one or more 3D models may be provided to an assembly descriptor 510 (e.g., the assembly descriptor 120 of FIG. 1), which may generate a graph-based representation 520 of the one or more 3D models as explained above with reference to FIGS. 3A-3C. In the example of FIG. 5A, the graph-based representation 520 is shown as an assembly graph that includes a set of nodes Nₐ that includes nodes 520a-520f, and a set of edges Eₐ (not labeled for simplicity of the drawing), each edge connecting a different pair of the nodes 520a-520f. However, as explained above with reference to FIGS. 3B and 3C, the graph-based representation may further include a component graph for one or more of the nodes 520a-520f, where the component graph includes feature related to each component of the assembly represented by the input 3D model(s).

The graph-based representation 520 generated by the assembly descriptor 510 may be passed to an encoder 530 (e.g., an encoder of the encoder/decoder 122 of FIG. 1). The encoder 530 may be configured to generate one or more graph embeddings 540 based on the graph-based representation output by the assembly descriptor 520. The graph embeddings 540 are provided to a decoder 570 (e.g., a decoder of the encoder/decoder 122 of FIG. 1). The decoder 570 may be configured to generate disassembly data 572 based on the graph embeddings 540 output by the encoder 530. The disassembly data 572 may specify an order in which components should be removed and a removal direction for each component. Exemplary details regarding operations of the encoder 530 and the decoder 570 are described in more detail below.

Referring to FIG. 5B, an architecture for an encoder for performing disassembly sequence planning in accordance with aspects of the present disclosure is shown. It is noted that the encoder architecture shown in FIG. 5B may be used by the encoder 530. As shown in FIG. 5B, the architecture of the encoder 530 may be a bi-level Graph Neural Network (GNN). The bi-level GNN of the encoder 530 may include a component convolutional network (GCN) 532 and an assembly GCN 538. The component GCN 532 may be configured to generate a set of graph embeddings 534 from the component graph. The graph embeddings 534 may then be integrated into the assembly graph as features of the nodes to produce assembly graph with node embeddings 536, which may be provided to the assembly GCN 538. The assembly GCN 538 may be configured to generate the graph embeddings 540 based on the assembly graph with node embeddings 536. Exemplary details regarding operations of the component GCN 532 and the assembly GCN 538 are described in more detail below.

Referring to FIG. 5C, a block diagram of illustrating aspects of a GCN architecture in accordance with aspects of the present disclosure are shown. As shown in FIG. 5C, the GCN architecture may include a GCN 550 configured to generate a set of node embeddings 552. Pooling 554 may be used to convert the set of node embeddings into a set of graph embeddings, such as the graph embeddings 534 or the graph embeddings 540 of FIG. 5B. In an aspect, the GCN 550 may utilize a message passing technique to generate the node embeddings 552.

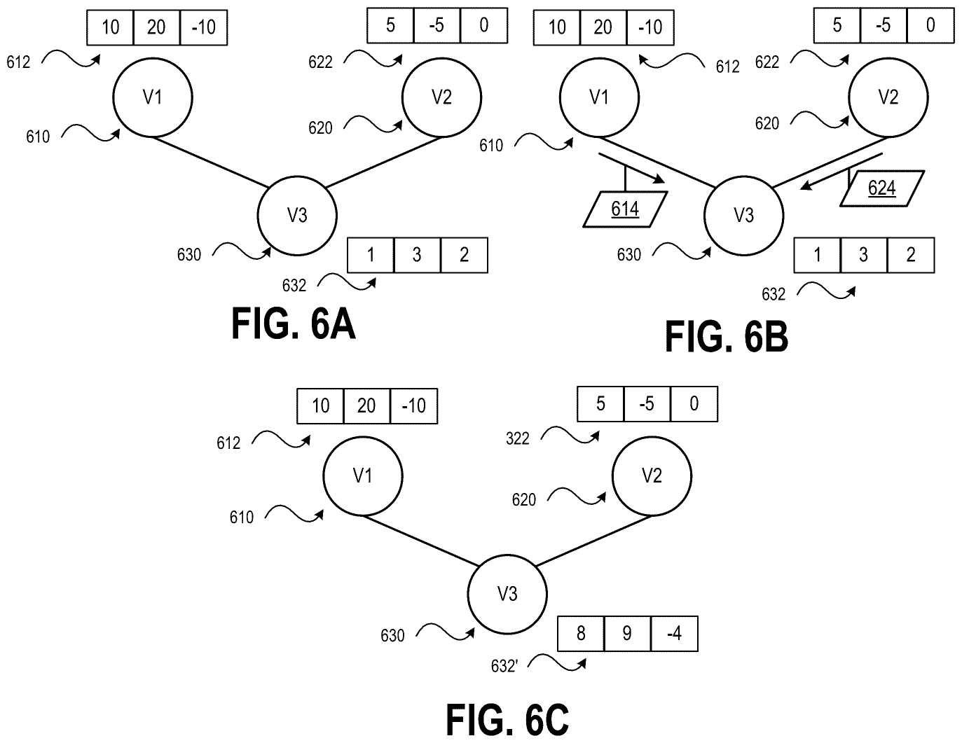

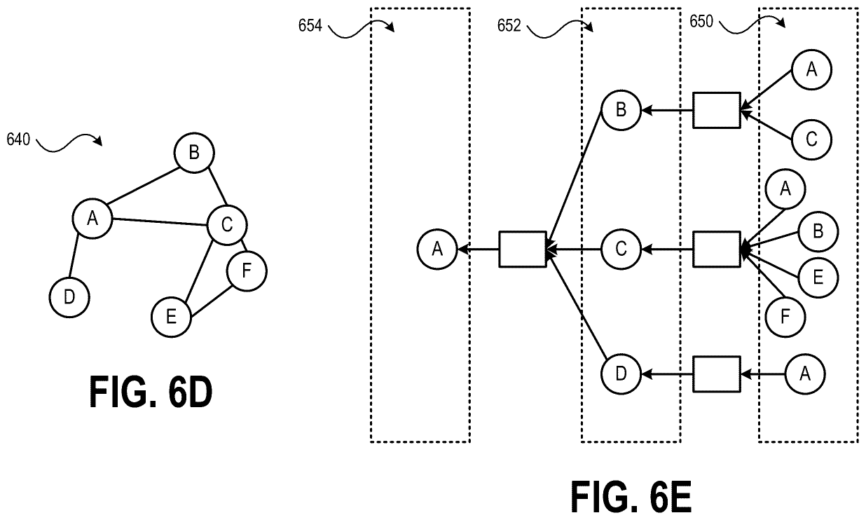

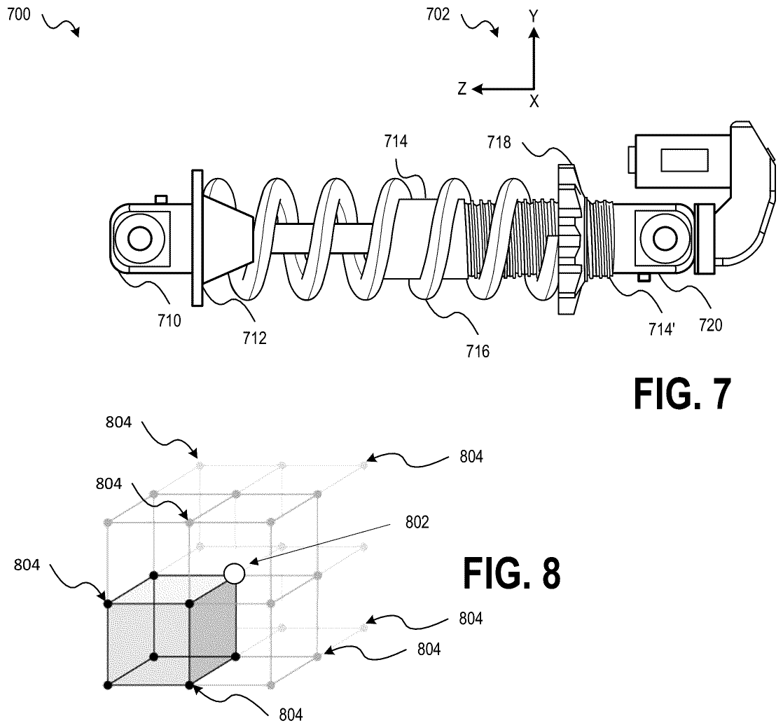

For example and referring to FIGS. 6A-6C, block diagrams illustrating exemplary operations for performing message passing during generation of graph embeddings in accordance with aspects of the present disclosure are shown. In FIGS. 6A-6C, three nodes 610, 620, 630 are shown. As shown in FIG. 6A, each node may include information, where node 610 includes information 612, node 620 includes 622, and node 630 includes information 632.

To update the information maintained by each node a message passing scheme may be used in which each node shares information with adjacent nodes. For example, as shown in FIG. 6B, the node 610 may pass a message 614 to the node 630 and the node 620 may pass a message 624 to the node 630. For example, the message 612 may include the information 610 and the message 624 may include the information 622. The node 630 may receive the messages 614, 624 and may use the information passed in the messages to update the information maintained by the node 630. For example, the information 632 maintained by the node 630 may initially (i.e., prior to the message passing phase) include values of 1, 3, 2. The information 612 received from the node 610 via the message 614 includes the values 10, 20, −10; and the information 612 received from the node 610 via the message 614 includes the values 5, −5, 0.

The node 630 may update the information 632 in response to receiving the information included in the messages 614, 624 to produce updated information 632′, as shown in FIG. 6C. In an aspect, the information maintained by each node may be updated during the message passing using an aggregation and averaging technique. For example, the values of the information 612, 622 received from the nodes 610, 620 may be aggregated as follows: 10+5=15, 20+(−5)=15, −10+=10). The information received by the node 630 as a result of the message passing phase may be similarly aggregated with the information 632 maintained by the node 630, resulting in temporary node information having values of 16 (e.g., 15+1), 18 (e.g., 15+3), and −8 (e.g., −10+2). The temporary information obtained via aggregation of the information 632 with the information 612, 622 obtained via the messages 614, 624 may then be averaged to obtain the updated information 632′ (e.g., 16/2=8, 18/2=9, −8/2=−4), as shown in FIG. 6C. In an aspect, the divisor used for the averaging operation may be determined based on the number of nodes from which a message is received (e.g., if the node 630 received messages from 3 nodes the information included in the messages may be aggregated and then divided by 3, instead of 2 as in the example above).

The exemplary message passing technique described above and illustrated with reference to FIGS. 6A-6C may be used by an encoder (the encoder 530 of FIG. 5A) to capture dependence information from different ones of the nodes of an assembly graph or component graph generated in accordance with aspects of the present disclosure. For example, as explained above, the encoder may include a GNN, which may be a deep neural network, that uses a graph data structure to capture the dependence of data. The GNN may utilize the message-passing strategy shown in FIGS. 6A-6C to update the representation of a node by aggregating transformed messages (representations) of its neighboring nodes. After ‘t’ iterations of message passing, a node's representation captures dependence from all the nodes within the t-hop neighborhood. Formally, a node v's representations at t^{th} layer is defined as:

$${{m}^{( t )}}_{u} = {{MSG}^{( t )}}_{u} . {h}^{( t - 1 )} , u ∈ \{ N ( v ) ⋃ v \}$$

$${{h}^{( t )}}_{v} = {AGG}^{( t )} . {{m}^{( t )}}_{u} , u ∈ N ( v ) , {{m}^{( t )}}_{v}$$

where, h^{(t)} is a feature representation of node v at t^{th} layer, m^{(t)} is the transformed message from neighborhood node u, N (v) is the set of nodes adjacent to v, AGG is the aggregation function (implemented as mean of neighborhood messages). In such notation, the initial node features for node v may be represented as h⁽⁰⁾.

It is noted that the examples described with reference to FIGS. 6A-6C demonstrate the concepts of message passing using a simplistic example involving 3 nodes, however, it should be understood that those concepts may be readily applied to more complex graphs having higher numbers of nodes. For example and referring to FIG. 6D, a graph 640 having 6 nodes, labeled as nodes A, B, C, D, E, F, with node A connected to nodes B, C, D; node B connected to nodes A, C; node C connected to nodes A, B, F, E; node E connected to nodes C, G; and node F connected to nodes C, E is shown. In such a graph, message passing may be performed as shown in FIG. 6E, which is a block diagram illustrating a multi-layered message passing arrangement. In particular, FIG. 6E shows a multi-layer message passing arrangement that includes a layer 0, shown by box 650, a layer 1, shown by box 652, and a layer 2, shown by box 654. As shown in FIG. 6E, during layer 0, nodes A, C may pass messages to node B; nodes A, B, E, F may pass messages to node C; and node A may pass a message to node D. Each node may generate updated information based on the received messages passed in layer 0 and may then pass messages via layer 1. For example, in layer 1, nodes B, C, D may pass updated information (e.g., information updated based on messages passed during layer 0) to node A. During layer 2, node A may generate updated information based on messages obtained from layer 1 message passing. In this manner, the information maintained by each of the nodes may be updated based on information passed from adjacent nodes, and the updated information generated by each node may also be passed (e.g., during layer 1) to further nodes, resulting in additional updates to the information maintained by each node. It is noted that while FIG. 6E illustrates three layers (e.g., layers 0, 1, 2), embodiments of the present disclosure may utilize message passing networks having more than three layers or less than three layers in particular implementations.

As can be appreciated from the description of FIGS. 6A-6E above and referring back to FIG. 5C, the GCN 550 may utilize message passing techniques to generate the set of node embeddings 552, which may correspond to a t^{th} iteration (or layer) of the message passing described above. As explained above, pooling 554 may be configured to consolidate the information passed during the message passing phase to produce the set of graph embeddings 534 or 540. It is noted that when the GCN architecture shown in FIG. 5C corresponds to the component GCN 532 of FIG. 5B, the input to the GCN may be a component graph and the graph embeddings produced by the pooling 554 may correspond to graph embeddings of the component graph. However, when the GCN architecture shown in FIG. 5C corresponds to the assembly GCN 538 of FIG. 5B, the input to the GCN may be an assembly graph with embeddings 536 of FIG. 5B, and the graph embeddings produced by the pooling 554 may correspond to graph embeddings 540, which represent an updated set of nodes features (e.g., based on the message passing and pooling). As can be appreciated from the foregoing, nodes (i.e., components) of the assembly graph may be represented by a feature vector that represents the component (e.g., the component graph) based on the component GCN 532 as described with reference to FIG. 5C. The assembly graph with embeddings 536 (e.g., embeddings derived from the component graph) is passed through next assembly GCN 538 to get an updated set of graph embeddings that includes updated node features derived from both the component graph (e.g., through incorporation of the component graph embeddings into the assembly graph, at 536 of FIG. 5B) and from the assembly graph with embeddings 536. As a result, a set of graph embeddings with updated node features is obtained (e.g., the graph embeddings 540 of FIG. 5B).

Referring back to FIG. 5A and as briefly described above, the decoder 570 may be configured to generate disassembly data 572 based on the graph embeddings 540 output by the encoder 530. The disassembly data 572 may indicate an order in which components of a product should be removed during disassembly, such as to indicate a particular component should be removed first, followed by another component, and then another component, and so on. Additionally, the disassembly data 572 may indicate a direction in which each component should be removed, as briefly described above with reference to FIGS. 4A-4C. In the description below, exemplary details of how the decoder 570 may generate the disassembly data 572 are described.

Referring to FIG. 5D, a block diagram illustrating an exemplary decoder for performing disassembly sequence planning in accordance with aspects of the present disclosure is shown. In an aspect, the decoder shown in FIG. 5D may be the decoder 570 of FIG. 5A. As explained above, the decoder 570 may be configured to generate the disassembly data 572 based on the graph embeddings 540 output by the decoder 530. In an additional or alternative aspect, the graph embeddings 540 may be aggregated to produce aggregate embeddings 540′, which may represent an embedding for an entire product (i.e., a single set of embeddings representing all components of a product), rather than including individual embeddings for each component of the product, as in the embeddings 540. In an aspect, the embeddings 540′ may be generated based on an average of the embeddings 540.

As shown in FIG. 5D, the embeddings 540 (or the embeddings 540′) may be provided to the decoder 570, which may be configured using recurrent neural network (RNN) architecture. For example, in the non-limiting example shown in FIG. 5D, the decoder 570 is shown as including a long-short term memory (LSTM) architecture with attention weights. The LSTM architecture shown in FIG. 5D includes a plurality of LSTM cells, shown as cells 582, 584, 586, 588. Each of the cells may include 3 inputs and may produce 2 outputs. For example, the cell 582, as the initial cell of the LSTM architecture, may be initialized using the graph embeddings 540 or 540′, which represent the initial hidden state (<SOS>), and an attention weight 590, which be based on aggregated values associated each embedding (e.g., h₀, h₁^{T}, h₂^{T}, . . . , hₙ^{T}). The cell 582 may output a component to be removed, shown in FIG. 5D as C₀ and a hidden state h₀. The hidden state may be passed to the next cell, as an input, along with the component to be removed as determined by the previous and an attention weight. For example, cell 584 may receive C₀ and h₀ from the cell 582, along with an attention weight 592 and may output a next component to be removed, shown as component C₁ and the hidden state h₁ of cell 584. Similarly, cell 586 may receive C₁ and h₁from the cell 584, along with an attention weight 594 and output a next component to be removed, shown as component C₂ and the hidden state h₂ of cell 584; cell 588 may receive Cₙ₋₁ and hₙ from the next to last cell (not shown in FIG. 5D for simplicity), along with an attention weight 596 and may output a last component to be removed, shown as component Cₙ.

As briefly explained above, the LSTM architecture shown in FIG. 5D is configured to predict the next component c, for removal and its removal direction dᵢ, which may be denoted as a state (1), where 1ᵢ=(cᵢ, dᵢ). It is noted that each state 1ᵢ may be conditioned on previous states 1₀, 1₁, . . . , 1ᵢ₋₁, such that, at step i, a particular cell is considering the state of the disassembly sequence that accounts for zero or more components previously designated for removal, and a hidden state hᵢ. Each cell also learns attention weights, which may be expressed as a context vector cxᵢ, that helps to focus the cell on specific components of the assembly when determining the i^{th} component to be removed during disassembly. The context vector cxᵢ may depend on the assembly graph's node embeddings (e.g., h^{T}, h^{T}, . . . , h^{T}). As explained above with reference to reference numerals 590-596, the context vector may be computed as the weighted sum of the node embeddings, which may be expressed as:

$${cx}_{i} = {x}_{j = 1}^{n - 1} \frac{{P}^{exp ( {e}_{ij} )}}{{}_{k = 1}^{n - 1} {exp}^{( {e}_{ik} )}} {h}_{j}^{T} ; {e}_{ij} = attn ( {s}_{i - 1} , {h}_{j} ) ,$$

where, attn is an attention model that assigns weights based on the relevance of the node (i.e., component) j in the assembly while predicting the i^{th} component. The weight may be based on a previous hidden state, sᵢ₋₁, as received from a previous cell, and the assembly graph's node embeddings h^{T}, ∀i∈ (0, n−1). The attention network may be modelled as a feed forward network which is jointly trained with other components of the decoder and graph encoder.

Referring briefly to FIG. 4D, a diagram illustrating aspects of using attention for disassembly sequence planning in accordance with aspects of the present disclosure is shown as a diagram 490. In the example of FIG. 4D, the diagram 490 indicates the attention weights associated with each component of the piston rod assembly 400 of FIG. 4A. As can be seen in FIG. 4A, the diagram 490 identifies each component of the piston rod assembly 400 along the left and bottom axes. At the intersection of each row and column the diagram 490 provides a heat map indicating the attention weight that should be given to other components when considering removal of one of the components. For example, column 422 of the diagram 490 indicates the attention weights associated with removal of the rod cap 420 and indicates (e.g., via the darker shading) the most attention should be given to the piston rod 430, which is the only component directly adjacent or connected to the rod cap 420. Similarly, the column 412 may be associated with removing the piston pin 410 and the pin bearing 440 is associated with the highest attention weight (e.g., because the pin bearing 440 is directly adjacent or connected to the piston pin 410). Similar weight indications are provided in column 434 for the piston rod, column 442 for the pin bearing, and column 454 for the piston head. Each column may be represented as a vector of attention weighs, with different weight values being associated with each of the different shades of color shown in the diagram 490. Such vectors of attention weights may correspond to the outputs shown by reference numbers 590-596 of FIG. 5D and may provide an indication that particular components of a product being disassembled are impacted or more relevant when considering removal of a certain component. For example, the attention weights indicated by the vector associated with column 422 may be associated with removal of the piston cap 420 and may indicate that the piston rod 430 is the component most directly impacted by the removal (e.g., because the piston cap 420 is directly attached to the piston rod 430 and not to other components).

Referring back to FIG. 5D, by passing the current state of each cell to the next, which may account for any component(s) that was removed by the previous cell(s), along with the attention weights, the decoder 570 may be enabled to determine which component(s) are most suitable for removal in a next step of the disassembly sequence being generated. After determining the next component to be removed, information indicating the component that was removed and a state of the product (e.g., based on the hidden layers) may be passed to the next cell, where this process may be repeated for all components of the product. As can be appreciated from the foregoing, the LSTM architecture illustrated in FIG. 5D provides functionality to support generation of a disassembly sequence plan that specifies an order in which each component of a product should be removed during a disassembly sequence.

However, as explained above, a decoder operating in accordance with aspects of the present disclosure may further be configured to determine a direction in which each component should be removed as part of the disassembly sequence plan. Referring briefly to FIG. 7, a block diagram illustrating exemplary operations determining a disassembly removal direction for a component in accordance with aspects of the present disclosure is shown. In particular, FIG. 7 shows 3D model of a shock absorber 700 that includes a mount 710, a bushing 712, a piston 714 having a threaded portion 714′, a spring 716, a lock 718, and a mount 720. The lock 718 may be rotated about the threaded portion 714′ of the piston 714 to adjust the tension on the spring 716. It is noted that not every component of the shock absorber 700 is labeled in FIG. 7 for simplicity but it should be understood that the disassembly sequence planning techniques disclosed herein may be readily utilized to provide a complete disassembly sequence plan for the shock absorber 700. Furthermore, it should also be understood that one or more of the components shown in FIG. 7 may itself be disassembled into sub-components. For example, the piston 714 may include multiple sub-components (e.g., a piston valve, a rod guide, absorber oil, piston rod, etc.) that may be disassembled.

To determine the direction for disassembling the shock absorber 700, a decoder (e.g., the decoder 570 of FIGS. 5A and 5D) may determine a principal axis of alignment for the model of the shock absorber 700. In the example shown in FIG. 7 this may be the z axis of legend 702. As the principal axis of alignment for the model of the shock absorber 700, when removing the mount 710 the decoder may determine the mount 710 should be moved along the z axis (and as explained above may further determine a direction along the z axis). In an aspect, the principal axis may be represented as a triple of the form (x, y, z) with binary values being used to indicate which axis is the primary axis. For example, the triple for the shock absorber 700 may be given by (0, 0, 1) to indicate the z axis is the primary axis. Once the principal axis is determined, directions for other components may be determined relative to the principal axis. For example, removal of the mount 720 may be determined as the triple (0, 0, −1), indicating the mount 720 should be removed in a direction opposite the principal axis. Further details regarding use of a principal axis of alignment of a 3D model for disassembly direction planning are described below.

An arbitrary direction \vec{d} may be expressed as a scalar multiple of three standard unit vectors, î, ĵ, \hat{k} along the x, y, z axes respectively, in the form:

$$\vec{d} = ( {d}_{1} , {d}_{2} , {d}_{3} ) = {d}_{1} \hat{ı} + {d}_{2} \hat{} + {d}_{3} \hat{k} .$$

To facilitate defining the unit vectors and determining the direction of removal for each component, a 3D assembly (e.g., an assembled product) may be aligned to a principal axis (direction) in 3D space. As explained above with reference to FIG. 7, every digital assembly (i.e., CAD model of a product) is aligned along a principal axis (i.e., direction) in 3D space, thereby providing a mechanism for determining the principal axis of alignment.

A disassembly direction may be associated with every component in an assembly when generating a disassembly sequence plan in accordance with aspects of the present disclosure, where each component is removed along its disassembly direction as part of the disassembly sequence. To determine the disassembly direction for each component, each LSTM cell may be configured with a direction predictor. The direction predictor may be a regression-based model configured to determine the exact values for d₁, d₂, d₃, which may then be used to determine the removal direction for disassembly (e.g., using the equation for \vec{d} described above).

In an additional or alternative aspect, a fixed or pre-determined number of disassembly directions may be configured for use by the direction predictor. For example, the fixed number of disassembly may be set at 26. As an example and referring to FIG. 8, a diagram illustrating a coordinate system having 26 directions is shown. In particular, the diagram of FIG. 8 includes 27 points, including an origin point 802 at the center surrounded by 26 points 804, corresponding to the 26 directions from the origin 802 (i.e., each of the 26 directions corresponds to a direction from the origin 802 to one of the points 804). It is noted that using a predetermined number of points may simplify training of the decoder while providing a robust number of directions for performing disassembly sequence planning. It is noted that other numbers of directions may be readily utilized by a direction predictor in accordance with aspects of the present disclosure and use of 26 directions has been provided for purposes of illustration, rather than by way of limitation.

In contrast to existing approaches, our framework generates a disassembly plan by using a trained deep neural network. By training our framework on different categories of 3D models, it learns the underlying representation of different components in these assemblies. Further, when this trained deep network encounters a new 3D model with components similar to those in the training dataset, the trained deep encoder generates a graph embedding, and the deep decoder uses this to generate the disassembly sequence of components.

Referring back to FIG. 5D, the cells of the LSTM of the decoder 570 may be configured to learn or determine the direction of removal for each component associated with the embeddings 540 (or 540′) and may output information associated with the direction, shown in FIG. 5D as outputs dr. As shown herein, the decoder 570 may be configured to accept a set of embeddings derived from an assembly graph and a component graph (e.g., the embeddings 540 or 540′) and may output a sequence or order in which specific components should be removed, as well as the direction d, for removing each component during disassembly.

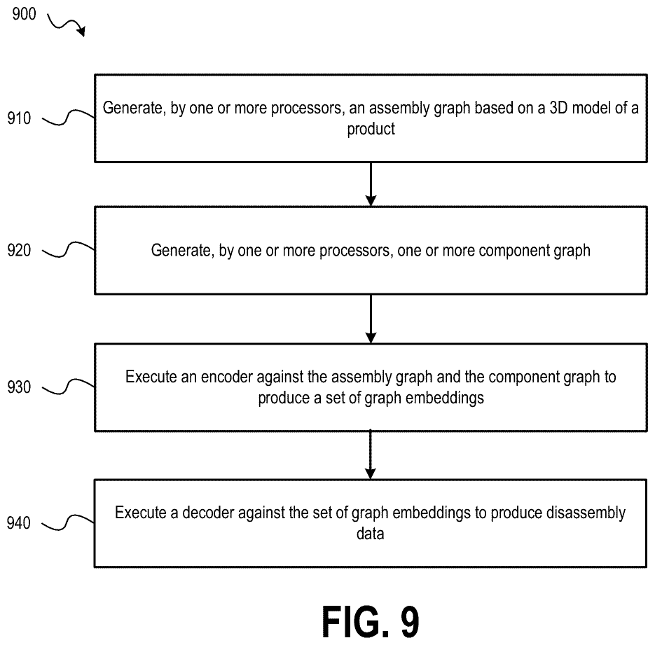

Referring to FIG. 9, a flow diagram of an exemplary method for performing disassembly sequence planning in accordance with aspects of the present disclosure is shown as a method 900. In an aspect, the method 900 may be performed by a computing device, such as the disassembly sequence planning device 110 of FIG. 1. In an aspect, steps of the method 900 may be stored as instructions (e.g., the instructions 116 of FIG. 1) that, when executed by one or more processors (e.g., the one or more processors 112 of FIG. 1), cause the one or more processors to perform operations for determining a disassembly sequence plan in accordance with the concepts disclosed herein.

At step 910, the method 900 includes generating, by one or more processors, an assembly graph based on a 3D model of a product. As explained above, the product may include a plurality of components. As explained above with reference to FIGS. 2A and 3A, the assembly graph may include a plurality of assembly nodes and a plurality of assembly edges. Each assembly node of the plurality of assembly nodes may represent a particular component of the plurality of components. A first assembly edge of the plurality of assembly edges may represent a relationship between a first component represented by a first assembly node of the plurality of assembly nodes and a second component represented by a second assembly node of the plurality of assembly nodes, where the first assembly node and the second assembly node are connected by the first assembly edge. In an aspect, the relationship between first component and the second component indicated by the first assembly edge may indicate the first component is in contact with or connected to the second component.

At step 920, the method 900 includes generating, by one or more processors, one or more component graphs based on the 3D model of the product. As explained above with reference to FIGS. 3A-3C, the product may include a plurality of components. The one or more component graphs includes a first component graph corresponding to a first component of the plurality of components (and other component graphs corresponding to other components). The first component graph may include a plurality of component nodes and a plurality of component edges. Each component node of the plurality of component nodes represents a portion of the first component, such as a face or surface of the component, as explained above with reference to FIGS. 3A-3C and each component edge of the first component graph may represent a relationship between different portions of the first component corresponding to a pair of component edges of the component graph. In an aspect, the first component graph may represent features of a particular assembly node of the assembly graph and other component graphs of the one or more component graphs may represent features of other assembly nodes of the assembly graph.

At step 930, the method 900 includes executing an encoder against the assembly graph and the one or more component graphs to produce a set of graph embeddings. In an aspect, the encoder executable by the one or more processors (e.g., the one or more processors 112 of FIGS. 1) and may be the encoder 530 of FIGS. 5A-5C. In an aspect, the encoder may be a bi-level encoder, as explained above with reference to FIGS. 5A-5C. In such an implementation, the set of graph embeddings may be generated by encoding the one or more component graphs to produce a set of component graph embeddings. The set of component graph embeddings may then be used to update features of the assembly graph to produce an updated assembly graph, and the updated assembly graph may be used to generate the set of graph embeddings provided to the decoder. In an aspect, the set of graph embeddings may be the graph embeddings 540 of FIG. 5B-5D. In an additional or alternative aspect, the set of graph embeddings may be the set of graph embeddings 540′ of FIG. 5D.

At step 940, the method 900 includes executing a decoder against the set of graph embeddings to produce disassembly data, wherein the decoder is executable by the one or more processors, and wherein the disassembly data identified an order in which to remove each component of the plurality of components during disassembly of the product. As explained above, the disassembly data may indicate a disassembly direction for each component of the plurality of components. In an aspect, the decoder may be configured to determine the disassembly direction for each component of the plurality of components based, at least in part, on a principal axis of alignment for the 3D model of the product, as explained above with reference to FIGS. 5D, 7, and 8. In an aspect, the decoder may be configured to determine the disassembly direction for each component of the plurality of components using a regression technique. In an additional or alternative aspect, the decoder may be configured to determine the disassembly direction for each component of the plurality of components based on a set of pre-determined directions, as explained above with reference to FIG. 8. In an aspect, the decoder may include a plurality of long-short term memory (LSTM) cells, as described above with reference to FIG. 5D. In such an implementation, a first cell of the plurality of LSTM cells may be configured to determine a first component of the plurality of components to be removed during disassembly of the product and to pass information identifying the first component and hidden state information to a second cell of the plurality of LSTM cells. The second cell may determine a second component to be removed and pass information identifying the second component and hidden state information of the second cell to a third cell, and so no. As additionally described above, the LSTM cells may be configured to utilize attention weights to determine the next component to be removed and may also be configured to determine the disassembly direction for each component.

As can be appreciated from the foregoing, the disassembly techniques disclosed herein represent an improved technique for performing disassembly sequence planning as compared to traditional techniques. In particular, the disassembly sequence planning approach disclosed herein provides a data driven approach to performing disassembly sequence planning that is not limited to specific products and does not require explicit mating information for the product. Instead, the disclosed disassembly sequence planning approach leverages information extracted from 3D models and graphing techniques to provide a generalized form of disassembly sequence planning that may be applied to any product and component. Additionally, through use of artificial intelligence techniques, such as the LSTM of the decoder, insights obtained when performing disassembly sequence planning for one product may be applied to other products, thereby improving the accuracy of the resulting disassembly sequence plans generated over time despite potentially diverse products being evaluated. Moreover, the disclosed disassembly sequence planning techniques may be performed in a computational efficient manner despite a large search space (i.e., a large number of components being involved) and can include disassembly direction indications as part of the output disassembly sequence plan.

An additional advantage of the disassembly techniques disclosed herein is that they are motivated by the observation that learning based methods have a great potential to learn the representation of data without manual feature engineering. One challenge to such training is the lack of ground truth information for CAD dataset, which are not readily available. Stated another way, to train the deep neural networks (e.g., the GCNs of the encoder 530), ground truth information of the data is need, but a CAD dataset with ground truth information for disassembly sequence plans does not exist. The techniques disclosed herein take a step forward to apply learning methods for disassembly sequence planning by introducing a CAD dataset that may be used to generate labelled disassembly sequence plans. By applying the techniques disclosed herein, a dataset containing industrial CAD models belonging to different categories may be generated with ground truth disassembly information, including the order of component removal and its disassembly direction. Such datasets may be used to further improve the ability to use learning techniques for disassembly sequence planning, thereby enabling further advancements and discoveries in the field of disassembly sequence planning.

Also, disassembly sequence plans determined using the method 900 and the concepts described above with reference to FIGS. 1-8 may also be used to generate disassembly instructions, which may include printed instructions, or may include executable instructions (e.g., code or commands) that may be used to program and/or control operations of one or more robots that may be used to perform a disassembly sequence determined using the techniques disclosed herein. For example, the instructions may be transmitted (e.g., by the disassembly sequence planning device 110 or one of the devices 140 of FIG. 1) to the one or more robots via a network or a wired or wireless interface.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The functional blocks and modules described herein (e.g., the functional blocks and modules in FIGS. 1-9) may comprise processors, electronics devices, hardware devices, electronics components, logical circuits, memories, software codes, firmware codes, etc., or any combination thereof. In addition, features discussed herein relating to FIGS. 1-9 may be implemented via specialized processor circuitry, via executable instructions, and/or combinations thereof.

As used herein, various terminology is for the purpose of describing particular implementations only and is not intended to be limiting of implementations. For example, as used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). The term “coupled” is defined as connected, although not necessarily directly, and not necessarily mechanically; two items that are “coupled” may be unitary with each other. The terms “a” and “an” are defined as one or more unless this disclosure explicitly requires otherwise. The term “substantially” is defined as largely but not necessarily wholly what is specified—and includes what is specified; e.g., substantially 90 degrees includes 90 degrees and substantially parallel includes parallel—as understood by a person of ordinary skill in the art. In any disclosed embodiment, the term “substantially” may be substituted with “within [a percentage] of” what is specified, where the percentage includes 0.1, 1, 5, and 10 percent; and the term “approximately” may be substituted with “within 10 percent of” what is specified. The phrase “and/or” means and or. To illustrate, A, B, and/or C includes: A alone, B alone, C alone, a combination of A and B, a combination of A and C, a combination of B and C, or a combination of A, B, and C. In other words, “and/or” operates as an inclusive or. Additionally, the phrase “A, B, C, or a combination thereof” or “A, B, C, or any combination thereof” includes: A alone, B alone, C alone, a combination of A and B, a combination of A and C, a combination of B and C, or a combination of A, B, and C.

The terms “comprise” and any form thereof such as “comprises” and “comprising,” “have” and any form thereof such as “has” and “having,” and “include” and any form thereof such as “includes” and “including” are open-ended linking verbs. As a result, an apparatus that “comprises,” “has,” or “includes” one or more elements possesses those one or more elements, but is not limited to possessing only those elements. Likewise, a method that “comprises,” “has,” or “includes” one or more steps possesses those one or more steps, but is not limited to possessing only those one or more steps.

Any implementation of any of the apparatuses, systems, and methods can consist of or consist essentially of—rather than comprise/include/have—any of the described steps, elements, and/or features. Thus, in any of the claims, the term “consisting of” or “consisting essentially of” can be substituted for any of the open-ended linking verbs recited above, in order to change the scope of a given claim from what it would otherwise be using the open-ended linking verb. Additionally, it will be understood that the term “wherein” may be used interchangeably with “where.”

Further, a device or system that is configured in a certain way is configured in at least that way, but it can also be configured in other ways than those specifically described. Aspects of one example may be applied to other examples, even though not described or illustrated, unless expressly prohibited by this disclosure or the nature of a particular example.

Those of skill would further appreciate that the various illustrative logical blocks, modules, circuits, and algorithm steps (e.g., the logical blocks in FIGS. 6-7) described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logical blocks, modules, and circuits described in connection with the disclosure herein may be implemented or performed with a general-purpose processor, a digital signal processor (DSP), an ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. Computer-readable storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, a connection may be properly termed a computer-readable medium. For example, if the software is transmitted from a website, server, or other remote source using a coaxial cable, fiber optic cable, twisted pair, or digital subscriber line (DSL), then the coaxial cable, fiber optic cable, twisted pair, or DSL, are included in the definition of medium. Disk and disc, as used herein, includes compact disc (CD), laser disc, optical disc, digital versatile disc (DVD), hard disk, solid state disk, and blu-ray disc where disks usually reproduce data magnetically, while discs reproduce data optically with lasers. Combinations of the above should also be included within the scope of computer-readable media.

The above specification and examples provide a complete description of the structure and use of illustrative implementations. Although certain examples have been described above with a certain degree of particularity, or with reference to one or more individual examples, those skilled in the art could make numerous alterations to the disclosed implementations without departing from the scope of this invention. As such, the various illustrative implementations of the methods and systems are not intended to be limited to the particular forms disclosed. Rather, they include all modifications and alternatives falling within the scope of the claims, and examples other than the one shown may include some or all of the features of the depicted example. For example, elements may be omitted or combined as a unitary structure, and/or connections may be substituted. Further, where appropriate, aspects of any of the examples described above may be combined with aspects of any of the other examples described to form further examples having comparable or different properties and/or functions, and addressing the same or different problems. Similarly, it will be understood that the benefits and advantages described above may relate to one embodiment or may relate to several implementations.

The claims are not intended to include, and should not be interpreted to include, means plus-or step-plus-function limitations, unless such a limitation is explicitly recited in a given claim using the phrase(s) “means for” or “step for,” respectively.

Although the aspects of the present disclosure and their advantages have been described in detail, it should be understood that various changes, substitutions and alterations can be made herein without departing from the spirit of the disclosure as defined by the appended claims. Moreover, the scope of the present application is not intended to be limited to the particular implementations of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method comprising:
generating, by one or more processors, an assembly graph based on a 3D model of a product, wherein the product comprises a plurality of components;
generating, by one or more processors, one or more component graphs, wherein the one or more component graphs are generated based on one or more components of the plurality of components of the product;
executing an encoder against the assembly graph and the one or more component graphs to produce a set of graph embeddings, the encoder executable by the one or more processors; and
executing a decoder against the set of graph embeddings to produce disassembly data, wherein the decoder is executable by the one or more processors, and wherein the disassembly data identifies an order in which to remove each component of the plurality of components during disassembly of the product.

2. The method of claim 1, wherein the disassembly data indicates a disassembly direction for each component of the plurality of components.

3. The method of claim 2, wherein the decoder is configured to determine the disassembly direction for each component of the plurality of components based, at least in part, on a principal axis of alignment for the 3D model of the product.

4. The method of claim 2, wherein the decoder is configured to determine the disassembly direction for each component of the plurality of components using a regression technique.

5. The method of claim 2, wherein the decoder is configured to determine the disassembly direction for each component of the plurality of components based on a set of pre-determined directions.

6. The method of claim 1, wherein the assembly graph includes a plurality of assembly nodes and a plurality of assembly edges, wherein each assembly node of the plurality of assembly nodes represents a particular component of the plurality of components, and wherein a first assembly edge of the plurality of assembly edges represents a relationship between a first component represented by a first assembly node of the plurality of assembly nodes and a second component represented by a second assembly node of the plurality of assembly nodes, and wherein the first assembly node and the second assembly node are connected by the first assembly edge.

7. The method of claim 6, wherein the relationship between first component and the second component indicates the first component is in contact with or connected to the second component.

8. The method of claim 6, wherein the one or more component graphs includes a first component graph corresponding to a first component of the plurality of components, wherein the first component graph comprises a plurality of component nodes and a plurality of component edges, and wherein each component node of the plurality of component nodes represents a portion of the first component, and wherein each edge of the first component graph represents a relationship between different portions of the first component corresponding to a pair of component edges of the component graph.

9. The method of claim 8, wherein the first component graph represents features of a particular assembly node of the assembly graph.

10. The method of claim 1, wherein the encoder is a bi-level encoder, and wherein the set of graph embeddings are generated by:
encoding the one or more component graphs to produce a set of component graph embeddings;
generating an updated assembly graph based on the set of component graph embeddings; and
generating the set of graph embeddings based on the updated assembly graph.

11. The method of claim 1, wherein the decoder comprises a plurality of long-short term memory (LSTM) cells, wherein a first cell of the plurality of LSTM cells is configured to determine a first component of the plurality of components to be removed during disassembly of the product and to pass information identifying the first component and hidden state information to a second cell of the plurality of LSTM cells.

12. A system comprising:
a memory;
one or more processors communicatively coupled to the memory;
an assembly descriptor executable by the one or more processors and configured to:
generate an assembly graph based on a 3D model of a product, wherein the product comprises a plurality of components; and
generate one or more component graphs based on the 3D model of the product, wherein the one or more component graphs are generated based on one or more components of the plurality of components of the product;
an encoder executable by the one or more processors and configured to produce a set of graph embeddings based on the assembly graph and the one or more component graphs; and
a decoder executable by the one or more processors and configured to generate disassembly data based on the set of graph embeddings, wherein the disassembly data identifies an order in which to remove each component of the plurality of components during disassembly of the product.

13. The system of claim 12, wherein the decoder is configured to determine a disassembly direction for each component of the plurality of components, wherein the disassembly direction is included in the disassembly data.

14. The system of claim 13, wherein the decoder is configured to determine the disassembly direction for each component of the plurality of components using a regression technique or based on a set of pre-determined directions.

15. The system of claim 12, wherein the assembly graph includes a plurality of assembly nodes and a plurality of assembly edges, wherein each assembly node of the plurality of assembly nodes represents a particular component of the plurality of components, and wherein a first assembly edge of the plurality of assembly edges represents a relationship between a first component represented by a first assembly node of the plurality of assembly nodes and a second component represented by a second assembly node of the plurality of assembly nodes, wherein the first assembly node and the second assembly node are connected by the first assembly edge, and wherein the relationship between first component and the second component indicates the first component is in contact with or connected to the second component.

16. The system of claim 15, wherein the one or more component graphs includes a first component graph corresponding to a first component of the plurality of components, wherein the first component graph comprises a plurality of component nodes and a plurality of component edges, wherein each component node of the plurality of component nodes represents a portion of the first component, and wherein each edge of the first component graph represents a relationship between different portions of the first component corresponding to a pair of component edges of the component graph, and wherein the first component graph represents features of a particular assembly node of the assembly graph.

17. The system of claim 12, wherein the encoder is a bi-level encoder that includes a component graph encoder configured to encode the one or more component graphs as a set of component graph embeddings and an assembly graph encoder configured to update the assembly graph based on the set of component graph embeddings to produce an updated assembly graph and to generate the set of graph embeddings based on the updated assembly graph.

18. The system of claim 12, wherein the decoder comprises a plurality of long-short term memory (LSTM) cells, wherein a first cell of the plurality of LSTM cells is configured to determine a first component of the plurality of components to be removed during disassembly of the product and to pass information identifying the first component and hidden state information to a second cell of the plurality of LSTM cells.

19. The system of claim 18, wherein each LSTM cell of the plurality of LSTM cells is configured to receive attention weight information and to determine a next component to be removed as part of the disassembly sequence based at least in part on the attention weight information.

20. A non-transitory computer-readable storage medium storing instructions that, when executed by one or more processors, cause the one or more processors to perform operations for generating disassembly data, the operations comprising:
generating an assembly graph based on a 3D model of a product, wherein the product comprises a plurality of components;
generating one or more component graphs, wherein the one or more component graphs are generated based on one or more components of the plurality of components of the product;
executing an encoder against the assembly graph and the one or more component graphs to produce a set of graph embeddings; and
executing a decoder against the set of graph embeddings to produce disassembly data, wherein the disassembly data identifies an order in which to remove each component of the plurality of components during disassembly of the product.
